(19) United States
(12) Patent Application Publication
(10) Pub. No.: US 2011/0304029 A1
(43) Pub. Date: Dec. 15, 2011

(54) SEMICONDUCTOR DEVICE AND MANUFACTURING METHOD THEREOF, WIRING BOARD AND MANUFACTURING METHOD THEREOF, SEMICONDUCTOR PACKAGE, AND ELECTRONIC APPARATUS

(76) Inventors: Yoshimichi Sogawa, Tokyo (JP); Takao Yamazaki, Tokyo (JP); Nobuaki Takahashi, Tokyo (JP)

(21) Appl. No.: 13/216,118

(22) Filed: Aug. 23, 2011

Related U.S. Application Data
(62) Division of application No. 11/720,066, filed on Jul. 26, 2007.

(30) Foreign Application Priority Data
Nov. 25, 2004 (JP) 2004-341002

(51) Int. Cl. H01L 23/58

(52) U.S. Cl. 257/632; 257/E23.002

(57) ABSTRACT

A terminal pad is formed on an active surface of an LSI chip, and a composite barrier metal layer is provided over this terminal pad. In the composite barrier metal layer, a plurality of low-elasticity particles composed of a silicone resin is dispersed throughout a metal base phase composed of NiP. The composite barrier metal layer has a thickness of, e.g., 3 μm, and the low-elasticity particles have a diameter of, e.g., 1 μm. A semiconductor device is mounted on a wiring board by bonding a solder bump to the composite barrier metal layer. The low-elasticity particles are thereby allowed to deform according to the applied stress when the semiconductor device is bonded to the wiring board via the solder bump, whereby the stress can be absorbed.

### TECHNICAL FIELD

The present invention relates to a semiconductor device connected via solder bumps to a wiring board, and a manufacturing method thereof; a wiring board to which a semiconductor device is connected via solder bumps, and a manufacturing method thereof; a semiconductor package comprising at least one of the semiconductor device and the wiring board; and an electronic apparatus comprising this semiconductor package.

### BACKGROUND ART

The demand for higher density in semiconductor devices increases with enhanced performance of electronic apparatuses. Recently, to meet these demands, flip chip bonding (hereinafter also referred to as FCB) has been used to mount semiconductor chips on carrier substrates and other such wiring boards. Flip chip bonding is a bonding method wherein multiple solder bumps are arranged in a matrix configuration on the active surface of a semiconductor chip, the active surface is turned to face the wiring board, and the semiconductor chip is bonded to the wiring board by means of the solder bumps. FCB has come to be used in various devices, particularly high-performance devices, because it enables more pins, smaller size, and faster signal transmission to be achieved in semiconductor devices.

Typically, when FCB is performed using solder bumps, a barrier metal having excellent solder diffusion prevention properties and wetting properties is provided to the surfaces of the pads; i.e., to the surfaces that come into contact with the solder bumps, in order to prevent the solder from diffusing into the semiconductor chip and the wiring board, and to improve the wetting properties of the solder bumps in regard to the pads.

In a semiconductor device obtained using FCB, there is a large difference between the thermal expansion coefficient of the organic resin substrate, ceramic substrate, or other substrate commonly used as the wiring board, and the thermal expansion coefficient of the semiconductor chip, which is primarily composed of silicon. Therefore, when a heat cycle is applied after the semiconductor chip is mounted on the wiring board, thermal stress originating from the difference in thermal expansion is applied to the solder bumps, and cracking occurs in the solder bumps. This phenomenon is a problem that is gradually becoming more prominent as the size of the solder bumps is reduced.

In addition to FCB, a bonding method known as CSP packaging), i.e., a method for bonding a semiconductor chip to a mounting substrate by means of solder bumps, is widely used in mobile devices that require high-density mounting. With semiconductor packages assembled through CSP, however, thermal stress and impact during dropping cause cracking in the portions bonded with the solder bumps and bring about connection defects. Particularly, since a large amount of force acts on the bases of the solder bumps in a brief amount of time during a fall, the bonding interfaces between the solder bumps and the barrier metal are likely to be damaged. This phenomenon is also a large problem in terms of reducing the surface areas of the bonding interfaces as a part of reducing the size of the solder bumps.

In view of this, several techniques have been proposed for reducing stress applied to the solder bumps in order to prevent damage to the solder bumps caused by thermal stress or impact during dropping, and to ensure that the bonding of the semiconductor package is reliable. Patent Document 1 (Japanese Laid-open Patent Application No. 2000-228455) and Patent Document 2 (Japanese Laid-open Patent Application No. 11-254185) disclose techniques for improving the softness of solder bumps and reducing stress by mixing an elastic substance into the solder bumps.

FIG. 21 is a cross-sectional view showing a bonded portion in the semiconductor package disclosed in Patent Document 1. in the semiconductor package disclosed in Patent Document 1, each bonded portion is provided with a solder ball 105 between a metal pad 102 formed on the bottom surface of tape 101 in which the semiconductor chip (not shown) is mounted on the top surface, and a metal pad 104 formed on the top surface of a wiring board 103, as shown in FIG. 21. The solder ball 105 is provided with a sphere 106 that is composed of heat-resistant silicon rubber and that has a diameter of 200 to 800 μm; an adhesive metal shell 107 that is composed of Au, Ag, Cu, Pd, Ni, or the like and that has a thickness of 1 to 5 μm is provided over the entire surface of the sphere 106; and a solder metal shell 108 that is composed of a solder and that has a thickness of 5 to 20 μm is provided over the entire outer surface of the adhesive metal shell 107. A solder paste 109 is provided between the metal pad 102 and the solder ball 105 and also between the metal pad 104 and the solder ball 105, and multiple resin balls 110 that are extremely small in diameter are dispersed throughout the solder paste 109. Patent Document 1 states that stress applied to the connection between the tape 101 and the wiring board 102 is thereby absorbed by the deformation of the sphere 106 composed of heat-resistant silicon rubber, and cracking and damage in the solder ball 105 can be prevented.

FIG. 22 is a cross-sectional view showing a flexible bonding material disclosed in Patent Document 2. Patent Document 2 discloses a flexible bonding material 113 wherein heat-resistant resin powder 112, whose particles are 3 to 30 μm in diameter, is contained in a spherical solder 111 that is 0.05 to 1.5 mm in diameter, as shown in FIG. 22. Patent Document 2 states that when an electronic component is bonded to a circuit board, the elasticity of the heat-resistant resin powder 112 can absorb thermal stress between the circuit board and the electronic component as a result of using the flexible bonding material 113 instead of a conventional solder ball.

Patent Document 3 (Japanese Laid-open Patent Application No. 11-54672) and Patent Document 4 (Japanese Laid-open Patent Application No. 2004-51755) disclose techniques for reducing stress applied to the solder bumps by introducing an electroconductive resin material in the electric current pathway between the semiconductor chip and the solder bumps.

FIG. 23 is a cross-sectional view showing the electronic component disclosed in Patent Document 3. Patent Document 3 discloses a technique for using an electroconductive resin to form terminals to which solder bumps are connected, as shown in FIG. 23. Specifically, a sub-substrate 122 is provided in an electronic component 121, and electrodes 123 are formed on the top surface of the sub-substrate 122. A flip chip 125 is connected to the electrodes 123 via bumps 124, and the bumps 124 are sealed by a band 126. Through-holes 127 are formed in parts of the areas directly beneath the electrodes 123 in the sub-substrate 122, and electroconductive resin layers 128 are provided in the through-holes 127. Metal plating layers 129 are provided on the bottom surfaces of the electroconductive resin layers 128, and solder bumps 130 are bonded to the metal plating layers 129. The purpose of the solder bumps 130 is to mount the sub-substrate 122 on a main substrate (not shown). Patent Document 3 states that in cases in which the sub-substrate 122 undergoes a heat cycle after being mounted on the main substrate, damage to the solder bumps 130 can be prevented because, as a result of the presence of the electroconductive resin layers 128 interposed between the electrodes 123 and the solder bumps 130, displacement caused by thermal stress between the sub-substrate 122 and the main substrate can be absorbed by the elastic deformation of the electroconductive resin layers 128.

FIG. 24 is a cross-sectional view showing the electroconductive bump disclosed in Patent Document 4. Patent Document 4 discloses a technique whereby an electroconductive filler 135 is included in a base phase composed of a rubbery elastic resin 134 in an electroconductive bump 133 provided on an electrode 132 of an electronic component 131, as shown in FIG. 24. This makes the electroconductive bump 133 elastic and capable of absorbing thermal stress. Patent Document 4 states that using whiskers coated on the surface with a metal layer for the electroconductive filler 135 increases the aspect ratio of the electroconductive filler 135 and enables whiskers of the electroconductive filler 135 to easily come into contact with each other. The electroconductivity of the electroconductive bump 133 can therefore be ensured, the content ratio of the electroconductive filler 135 can be reduced, and the flexibility of the electroconductive bump 133 can be further improved.

Furthermore, Patent Document 5 (Japanese Laid-open Patent Application No. 2002-118199) and Patent Document 6 (Japanese Laid-open Patent Application No. 2003-124389) disclose a technique for reducing stress applied to solder bumps by erecting posts on a semiconductor chip and providing the solder bumps on the top surfaces of the posts.

FIG. 25 is a cross-sectional view showing the semiconductor device disclosed in Patent Document 5. Patent Document 5 discloses a technique in which posts 143 are provided between a semiconductor chip 141 and a solder bump 142, and stress-reducing elements 144 composed of an anisotropic electroconductive material, or of Au, Pd, or another metal having a low Young's modulus, are introduced into the middle portions of the posts 143, as shown in FIG. 25. The posts 143 are connected to electrode pads 145 formed on the surface of the semiconductor chip 141, and the peripheries of the posts 143 are sealed by a sealing resin 146. Thermal stress applied to the solder bump 142 can be reduced by providing the posts 143 in this semiconductor device. Patent Document 5 states that stress applied to the posts 143 can be more effectively reduced by providing the posts 143 with the stress-reducing elements 144.

FIG. 26 is a cross-sectional view showing the semiconductor package disclosed in Patent Document 6. Patent Document 6 discloses a technique for providing an insulating layer 152 on an Si wafer 151, forming a resinous protrusion 153 on the insulating layer 152, and providing an electroconductive layer 155 so as to cover the resinous protrusion 153 and to form a connection with an Al pad 154 formed in the surface of the Si wafer 151, as shown in FIG. 26. A post 156 is formed by the resinous protrusion 153 and the electroconductive layer 155 that covers the protrusion, and a solder bump 157 is connected to the top surface of the post 156. A sealing resin layer 158 is provided around the periphery of the post 156, and a groove 159 is formed in the portion on the top surface of the sealing resin layer 158 that encircles the post 156. Stress applied to the solder bump 157 can be reduced by providing the post 156 between the Si wafer 151 and the solder bump 157 in this semiconductor package. Patent Document 6 states that providing the resinous protrusion 153 within the post 156 enables stress applied to the post 156 to be more efficiently absorbed by the deformation of the resinous protrusion 153, and that stress applied to the post 156 can be even more effectively absorbed because forming the groove 159 in the sealing resin layer 158 can prevent the sealing resin layer 158 from restricting the deformation of the post 156.

Patent Document 1: Japanese Laid-open Patent Application No. 2000-228455 (FIG. 3)

Patent Document 2: Japanese Laid-open Patent Application No. 11-254185 (FIG. 1)

Patent Document 3: Japanese Laid-open Patent Application No. 11-54672 (FIG. 1)

Patent Document 4: Japanese Laid-open Patent Application No. 2004-51755 (FIG. 7)

Patent Document 5: Japanese Laid-open Patent Application No. 2002-118199 (FIG. 1)

Patent Document 6: Japanese Laid-open Patent Application No. 2003-124389 (FIG. 1)

### DISCLOSURE OF THE INVENTION

### Problems the Invention Is Intended to Solve

However, the conventional techniques described above are subject to the following problems. In the techniques disclosed in Patent Documents 1 and 2; i.e., in the techniques for improving the softness of the solder bumps and reducing stress by mixing an elastic substance into the solder bumps, the solder bumps, which have low strength and are easily damaged compared to the other metal parts, are further reduced in strength, and the solder bumps therefore are all the more easily damaged. A metal layer that is easily wetted by the solder must be formed on the surface of the resin material in advance in order to uniformly disperse the resin material throughout the base phase composed of the solder, which increases costs.

The following problems are encountered in the techniques disclosed in Patent Documents 3 and 4; i.e., in the techniques for reducing stress by introducing an electroconductive resin material into the electric current pathway between the semiconductor chip and the solder bumps. Electroconductivity is achieved by dispersing metal microparticles into the base phase composed of an insulating resin in the electroconductive resin material. However, electrical resistance is fairly high in the electroconductive resin material because the electroconductivity is merely provided by point contact between the metal microparticles. Therefore, a semiconductor package in which an electroconductive resin material is introduced into the electric current pathway can only be applied in a limited number of devices, even if the devices have high electrical resistance, such as a liquid crystal device. The same applies to an electroconductive adhesive.

Furthermore, the following problems are encountered in the techniques disclosed in Patent Documents 5 and 6; i.e., in the techniques for reducing stress applied to solder bumps by erecting posts on a semiconductor chip and connecting the solder bumps on the top surfaces of the posts. Specifically, when posts are erected on a semiconductor chip, the semiconductor package becomes thicker in proportion to the posts. The productivity of manufacturing semiconductor packages is reduced because time is required to form the posts. Furthermore, as shown in Patent Document 5, in cases in which stress-reducing members are placed in the intermediate portions of the posts, stress is not sufficiently reduced if the stress-reducing members are formed from metal, and electroconductivity is low if the stress-reducing members are formed from an anisotropic electroconductive film.

The present invention was designed in view of these problems, and an object thereof is to provide a semiconductor device and manufacturing method thereof wherein stress applied to solder bumps can be absorbed while keeping costs low, without reducing the strength of the solder bumps, increasing electrical resistance, or increasing the thickness of the semiconductor package; to provide a wiring board and manufacturing method thereof; to provide a semiconductor package comprising at least one of the semiconductor device and wiring board; and to provide an electronic apparatus comprising this semiconductor package.

### Means for Solving the Problems

The semiconductor device according to the present invention is characterized in comprising a semiconductor chip having a terminal pad on a surface, and a barrier metal layer provided over the terminal pad; wherein the barrier metal layer has a base phase composed of an electroconductive material, and a plurality of low-elasticity particles that are dispersed in the base phase and that have a lower modulus of elasticity than does the base phase.

In the present invention, when the semiconductor device is bonded to a wiring board via a solder bump, the applied stress can be absorbed by deformation of the low-elasticity particles in accordance with the stress.

The semiconductor device according to the present invention preferably comprises an adhesion-enhancing layer composed of an electroconductive material and provided between the terminal pad and the barrier metal layer. Adhesion between the terminal pad and the barrier metal layer can thereby be improved. This adhesion-enhancing layer is preferably formed from the same material as the electroconductive material that forms the base phase. This results in satisfactory adhesion between the adhesion-enhancing layer and the barrier metal layer.

Furthermore, the semiconductor device according to the present invention preferably comprises a detachment prevention layer composed of an electroconductive material and provided over the barrier metal layer. The low-elasticity particles can thereby be prevented from being shed by the barrier metal layer.

It is also preferred that the content ratio of low-elasticity particles in the barrier metal layer continuously vary in the film thickness direction of the barrier metal layer, and the content ratio of low-elasticity particles in the bottom and top layer of the barrier metal layer be less than the content ratio of low-elasticity particles in the intermediate portion between the bottom and top layers. Thereby, adhesion between the terminal pad and the barrier metal layer can be improved, the low-elasticity particles can be prevented from being shed by the barrier metal layer, and stress does not concentrate in the interfaces because the interfaces are not located in the barrier metal layer.

The wiring board according to the present invention is characterized in comprising a wiring board main body having a terminal pad on a surface, and a barrier metal layer provided over the terminal pad; wherein the barrier metal layer has a base phase composed of an electroconductive material, and a plurality of low-elasticity particles that are dispersed in the base phase and that have a lower modulus of elasticity than does the base phase.

In the present invention, when a semiconductor device is bonded to the wiring board via a solder bump, the applied stress can be absorbed by deformation of the low-elasticity particles in accordance with the stress.

The semiconductor package according to the present invention is characterized in comprising a wiring board, a semiconductor device mounted on the wiring board, and a solder bump for bonding a terminal pad of the semiconductor device to a terminal pad of the wiring board; wherein the semiconductor device is the semiconductor device according to the previously described present invention.

Another semiconductor package according to the present invention is characterized in comprising a wiring board, a semiconductor device mounted on the wiring board, and a solder bump for bonding a terminal pad of the semiconductor device to a terminal pad of the wiring board; wherein the wiring board is the wiring board according to the previously described present invention.

Yet another semiconductor package according to the present invention is characterized in comprising a wiring board, a semiconductor device mounted on the wiring board, and a solder bump for bonding a terminal pad of the semiconductor device to a terminal pad of the wiring board; wherein the semiconductor device is the semiconductor device according to the previously described present invention, and the wiring board is the wiring board according to the previously described present invention.

Preferably, an intermetallic compound layer, formed by alloying the electroconductive material constituting the base phase and the solder constituting the solder bump, is formed between the barrier metal layer and the solder bump, and the low-elasticity particles are also dispersed in the intermetallic compound layer. It is thereby possible to prevent the intermetallic compound layer from being damaged by cracks when stress is applied.

The electronic apparatus according to the present invention is characterized in comprising the semiconductor package. This electronic apparatus may be a portable phone, a notebook computer, a desktop personal computer, a liquid crystal device, an interposer, or a module.

The method for manufacturing the semiconductor device according to the present invention is characterized in comprising a step for forming a barrier metal layer on a terminal pad on a surface of a semiconductor wafer by plating the pad with a plating solution containing low-elasticity particles, wherein a plurality of low-elasticity particles composed of a material having a lower modulus of elasticity than does a base phase composed of an electroconductive material is dispersed in the base phase; and a step for cutting the semiconductor wafer into a plurality of semiconductor chips by dicing.

In the step for forming the barrier metal layer, the semiconductor wafer is dipped into a single plating bath, and the temperature, pH, or stirring conditions of the plating bath are varied during buildup of the barrier metal layer, whereby the content ratio of low-elasticity particles in the barrier metal layer can be continuously varied in the film thickness direction of the barrier metal layer, and the content ratio of low-elasticity particles in the bottom and top layers of the barrier metal layer can be reduced to less than the content ratio of low-elasticity particles in the intermediate portion between the bottom and top layers. It is thereby possible to enhance adhesion between the terminal pad and the barrier metal layer, to prevent the low-elasticity particles from being shed by the barrier metal layer, and to form barrier metal layers in which stress does not concentrate in the interfaces because the interfaces are not located in the barrier metal layer.

Furthermore, the step for forming the barrier metal layer may comprise a step for setting the temperature of the plating bath to a first temperature and building up the barrier metal layer, a step for changing the temperature of the plating bath from the first temperature to a second temperature that is higher than the first temperature and building up the barrier metal layer, and a step for changing the temperature of the plating bath from the second temperature to a third temperature that is lower than the second temperature and building up the barrier metal layer.

The method for manufacturing the wiring board according to the present invention is characterized in comprising a step for forming a barrier metal layer on a terminal pad on a surface of a wiring board main body by plating the pad with a plating bath containing low-elasticity particles, wherein a plurality of low-elasticity particles composed of a material having a lower modulus of elasticity than does a base phase composed of an electroconductive material is dispersed in the base phase.

### Effects of the Invention

According to the present invention, dispersing low-elasticity particles in the barrier metal layer allows the low-elasticity particles to deform when stress is applied to a semiconductor device. It is therefore possible to obtain a semiconductor device in which stress applied to solder bump can be absorbed and in which the costs can be kept low without reducing the strength of the solder bump, increasing electrical resistance, or making the semiconductor package thicker.

### BRIEF DESCRIPTION OF THE DRAWINGS

FIG. 1 is a cross-sectional view showing the semiconductor device according to Embodiment 1 of the present invention;

FIG. 2 is a cross-sectional view showing the semiconductor device according to Embodiment 3 of the present invention;

FIG. 3 is a cross-sectional view showing the semiconductor device according to Embodiment 5 of the present invention;

FIG. 4 is a partially enlarged cross-sectional view showing a semiconductor device that is not provided with a detachment prevention layer;

FIG. 5 is a partially enlarged cross-sectional view showing the semiconductor device according to the present embodiment;

FIG. 6 is a cross-sectional view showing the semiconductor device according to Embodiment 7 of the present invention;

FIG. 7 is a cross-sectional view showing the semiconductor device according to Embodiment 8 of the present invention;

FIG. 8 is a cross-sectional view showing the wiring board according to Embodiment 10 of the present invention;

FIG. 9 is a cross-sectional view showing the wiring board according to Embodiment 12 of the present invention;

FIG. 10 is a cross-sectional view showing the wiring board according to Embodiment 13 of the present invention;

FIG. 11 is a cross-sectional view showing the wiring board according to Embodiment 14 of the present invention;

FIG. 12 is a cross-sectional view showing the wiring board according to Embodiment 15 of the present invention;

FIG. 13 is a cross-sectional view showing the semiconductor package according to Embodiment 16 of the present invention;

FIG. 14 is a cross-sectional view showing the semiconductor package according to Embodiment 17 of the present invention;

FIG. 15 is a cross-sectional view showing the semiconductor package according to Embodiment 18 of the present invention;

FIG. 16 is a cross-sectional view showing the semiconductor package according to Embodiment 19 of the present invention;

FIG. 17 is a cross-sectional view showing the semiconductor package according to Embodiment 20 of the present invention;

FIG. 18 is a cross-sectional view showing the semiconductor package according to the twenty-Embodiment 1 of the present invention;

FIG. 19 is a cross-sectional view showing the semiconductor package according to Embodiment 22 of the present invention;

FIG. 20 is a cross-sectional view showing the semiconductor package according to Embodiment 23 of the present invention;

FIG. 21 is a cross-sectional view showing the bonded portion in the semiconductor package disclosed in Patent Document 1;

FIG. 22 is a cross-sectional view showing the flexible bonding material disclosed in Patent Document 2;

FIG. 23 is a cross-sectional view showing the electronic component disclosed in Patent Document 3;

FIG. 24 is a cross-sectional view showing the electroconductive bump disclosed in Patent Document 4;

FIG. 25 is a cross-sectional view showing the semiconductor device disclosed in Patent Document 5; and

FIG. 26 is a cross-sectional view showing the semiconductor package disclosed in Patent Document 6.

### KEY

1, 11, 13, 15, 16: semiconductor device

2: LSI chip

2a: active surface

3: terminal pad

4: passivation film

4a: aperture

5: composite barrier metal layer

6: metal base phase

7: low-elasticity grain

12: adhesion-enhancing layer

14: detachment prevention layer

17: composite barrier metal layer

18, 20: layer poor in low-elasticity particles

19: layer rich in low-elasticity particles

21, 26, 27, 28, 29: wiring board

22: wiring board main body

22a: mounting surface

23: terminal pad

24: solder resist

24a: aperture

31, 36, 38, 39, 40, 41, 42, 43: semiconductor package

32: wiring board

33: barrier metal layer

34: solder bump

37: intermetallic compound layer

44: core ball

45: solder layer

46: solder ball

47: solder paste

101: tape

102: metal pad

103: wiring board

104: metal pad

105: solder ball

106: sphere

107: adhesive metal shell

108: solder metal shell

109: solder paste

110: resin ball

111: solder

112: heat-resistant resin powder

113: flexible bonding material

121: electronic component

122: sub-substrate

123: electrode

124: bump

125: flip chip

126: band

127: through-hole

128: electroconductive resin layer

129: metal plating layer

130: solder bump

131: electronic component

132: electrode

133: solder bump

134: rubbery elastic resin

135: electroconductive filler

141: semiconductor chip

142: solder bump

143: post

144: stress-reducing material

145: electrode pad

146: sealing resin

151: Si wafer

152: insulating layer

153: resinous protrusion

154: Al pad

155: electroconductive layer

156: post

157: solder bump

158: sealing resin layer

159: groove

### BEST MODE FOR CARRYING OUT THE INVENTION

Next, embodiments of the present invention will be described in detail with reference to the attached diagrams

### Embodiment 1

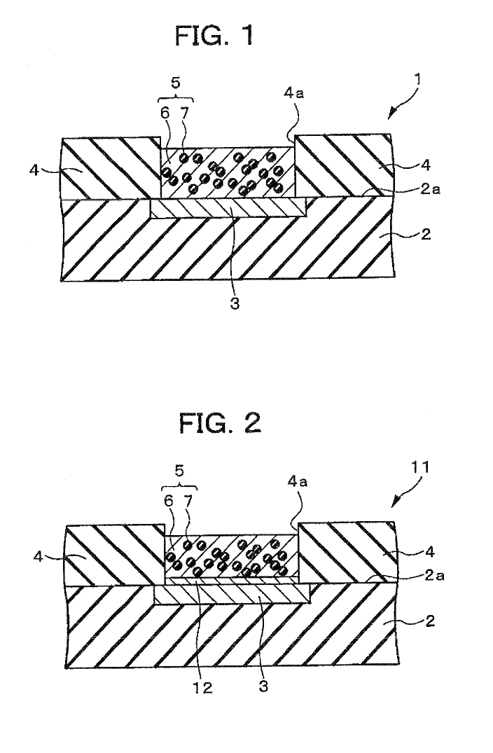

Embodiment 1 of the present invention will now be described. FIG. 1 is a cross-sectional view showing the semiconductor device according to the present embodiment. The semiconductor device 1 according to the present embodiment has an LSI (Large Scale Integrated circuit) chip 2 as a semiconductor chip, as shown in FIG. 1. The LSI chip 2 has an LSI formed on the surface of a silicon chip, and a terminal pad 3 composed of, e.g., aluminum (Al), is formed on an active surface 2a thereof. A passivation film 4 is provided on the active surface 2a of the LSI chip 2, and an aperture 4a is formed in the area of the passivation film 4 directly above the terminal pad 3.

A composite barrier metal layer 5 is provided over the terminal pad 3; i.e., in the aperture 4a. In this composite barrier metal layer 5, low-elasticity particles 7 composed of, e.g., a silicone resin, are dispersed in a metal base phase 6 composed of, e.g., NiP. The low-elasticity particles 7 have a spherical shape, for example. The modulus of elasticity of the low-elasticity particles 7 is less than the modulus of elasticity of the metal base phase 6. The thickness of the composite barrier metal layer 5 may, for example, be 1 to 10 μm, and specifically 3 μm. The diameter of the low-elasticity particles 7 may, for example, be 0.01 to 5 μm, and is less than the thickness of the composite barrier metal layer 5, or 1 μm, for example. The diameter of the low-elasticity particles 7 is preferably a fraction of the thickness of the composite barrier metal layer 5.

The following is a description of the operation of the semiconductor device according to the present embodiment thus configured. The semiconductor device 1 according to the present embodiment has a solder bump (not shown) placed on the composite barrier metal layer 5, and is mounted on a wiring board (not shown) via this solder bump to form a semiconductor package. Specifically, the wiring board is disposed on the side of the LSI chip 2 that faces the active surface 2a. The terminal pad 3 of the LSI chip 2 is connected to the terminal pad of the wiring board via the composite barrier metal layer 5 and the solder bump.

When the semiconductor package is subjected to a heat cycle, the difference between the thermal expansion coefficients of the LSI chip 2 and the wiring board produces thermal stress between the LSI chip 2 and the wiring board. At this time, the low-elasticity particles 7 in the composite barrier metal layer 5 undergo deformation, whereby deformation is produced in the entire composite barrier metal layer 5, and the thermal stress is absorbed.

Next, the effects of the present embodiment will be described. When thermal stress is applied in the wiring board on which the semiconductor device 1 is mounted in the semiconductor device 1 according to the present embodiment, the deformation of the composite barrier metal layer 5 and the absorption of the thermal stress in the layers can prevent the solder bump from being damaged. The presence of the composite barrier metal layer 5 can prevent the solder from diffusing into the terminal pad 3 and diffusing into the LSI chip 2 when the solder bump melts. Since the metal base phase 6 of the composite barrier metal layer 5 is formed from NiP, which has low electrical resistivity, providing the composite barrier metal layer 5 can prevent electrical resistance between the terminal pad 3 and the solder bump from increasing. Furthermore, in the present embodiment, applied stress can be reduced without reducing the strength of the solder bump, because low-elasticity particles composed of a silicone resin are dispersed in barrier metal layer that is stronger than the solder bump. Furthermore, according to the present embodiment, the semiconductor device does not increase in thickness because a composite barrier metal layer is provided instead of conventional barrier metal layer.

In the present embodiment, an example was shown in which the metal base phase 6 of the composite barrier metal layer 5 was formed from NiP, but the present invention is not limited to this option alone, and the base phase may also be formed from another metal or alloy. The material of the metal base phase 6 preferably has high electroconductivity, and is preferably a metal or an alloy containing one or more metals selected from Ni, Cu, Fe, Co, and Pd, for example. In addition to the function of preventing the solder from diffusing into the LSI chip 2, the composite barrier metal layer 5 can also be provided with high electroconductivity, which is not obtained with conventional electroconductive resins and electroconductive adhesives.

In the present embodiment, an example was shown in which a silicone resin was used as the material of the low-elasticity particles 7, but the present invention is not limited to this option alone, and other options include using a fluorine resin, an acrylic resin, a nitrile resin, a urethane resin, or the like; a mixture of these resins; or a mixture of particles composed of a plurality of forms of these resins. Also, an example was shown in which the low-elasticity particles 7 were spherical in shape, but the present invention is not limited to this option alone, and the particles may also be acicular, flat, cubic, or otherwise non-spherical. Spheres are the most preferred shape for the low-elasticity particles 7 because they are easily manufactured and have a high deformation capability in response to stress applied from any direction. The size of the low-elasticity particles 7, i.e., the diameter when the shapes of the low-elasticity particles 7 are spherical, or the major axis when the shapes are non-spherical, are preferably less than the size of the composite barrier metal layer 5. This is because the low-elasticity particles 7 are easily incorporated into the composite barrier metal layer 5 when their size is smaller than the thickness of the composite barrier metal layer 5. The actual size of the low-elasticity particles 7 is preferably approximately 0.01 to 5 μm, because excessively small low-elasticity particles 7 are difficult to manufacture.

To obtain the stress-reducing effect, the content ratio of the low-elasticity particles 7 in the composite barrier metal layer 5 is preferably kept high while remaining within a range in which electrical resistivity is not too high. The low-elasticity particles 7 are preferably dispersed uniformly throughout the metal base phase 6. This is because the composite barrier metal layer 5 deform more easily in response to external force when the low-elasticity particles 7 are dispersed as islands and the metal base phase 6 takes on a sponge-shaped structure.

Furthermore, the material of the terminal pad 3 is not limited to Al, and may also be copper (Cu), for example The substrate of the LSI chip 2 is not limited to Si, and may be another semiconductor material.

### Embodiment 2

Next, Embodiment 2 of the present invention will be described. The present embodiment is an embodiment of the method for manufacturing the semiconductor device according to the previously described Embodiment 1. First, an LSI (not shown) is formed on the surface of a silicon wafer, and a terminal pad 3 composed of Al is formed on an active surface thereof, as shown in FIG. 1. Next, a passivation film 4 is foamed on the active surface of the silicon wafer. An aperture 4a is formed in the passivation film 4 directly above the terminal pad 3, and the terminal pad 3 is exposed. A zincate treatment is applied to cover the surfaces of the terminal pad 3 with zinc (Zn). The silicon wafer is then dipped in an electroless NiP plating solution that contains a silicone resin and that has a surfactant added thereto. An NiP layer is thereby built up in the aperture 4a of the passivation film 4, i.e., on the terminal pad 3, but the silicone resin is incorporated into the NiP layer at this time, and the metal base phase 6 composed of NiP and the low-elasticity particles 7 composed of a silicone resin coprecipitate and form a composite. The composite barrier metal layer 5 is thereby formed.

At this time, the content ratio of low-elasticity particles 7 in the composite barrier metal layer 5 can be controlled by adjusting the content ratio of the silicone resin in the electroless NiP plating solution, by adjusting the rate of precipitation, or by selecting the type of surfactant. The thickness of the composite barrier metal layer 5 can be arbitrarily controlled by adjusting the plating treatment time, the plating treatment temperature, and other such factors. In the present embodiment, the thickness of the composite barrier metal layer 5 may, for example, be 1 to 10 μm, and specifically 3 μm.

Next, the LSI chip 2 is produced by dicing the silicon wafer. The semiconductor device 1 is thereby manufactured.

In the present embodiment, the composite barrier metal layer 5 can be formed by the previously described method without using more steps than in a case in which a conventional barrier metal is formed without the use of low-elasticity particles. A composite barrier metal layer 5 can thereby be formed at low cost and with high productivity.

In cases in which the material of the terminal pad 3 is other than Al, such as Cu or the like, electroless NiP plating can be applied after performing Pd catalysis instead of a zincate treatment. Thus, by solely varying the pretreatment of electroless NiP plating, a composite barrier metal layer can be formed in cases in which the terminal pad 3 is composed of Cu and in cases in which the pad is composed of Al.

The material of the metal base phase 6 of the composite barrier metal layer 5 is not limited to NiP and may also be Cu, Pd, Co, Fe, or another metal or an alloy thereof. Furthermore, a composite barrier metal layer can be formed through electroplating instead of electroless plating by forming a sheet layer as a continuity layer on the terminal pad 3, and selecting an area for plating by a photolithography process. The low-elasticity particles and the metal base phase can also be made to coprecipitate by dispersing the low-elasticity particles in the plating bath in cases in which the composite barrier metal layer is formed by electroplating. In this case, the material of the precipitated metal base phase may be any metal or alloy as long as the material can be electroplated and can prevent the solder from diffusing.

Furthermore, an Au layer with a thickness of approximately 0.05 to 0.3 μm may be formed by electroless Au plating on the surface of the composite barrier metal layer 5. Thereby, the composite barrier metal layer 5 can be prevented from oxidizing and the wettability of the solder can be improved.

### Embodiment 3

Next, Embodiment 3 of the present invention will be described. FIG. 2 is a cross-sectional view showing a semiconductor device according to the present embodiment. The semiconductor device 11 according to the present embodiment differs from the semiconductor device 1 (see FIG. 1) according to the previously described Embodiment 1 in that an adhesion-enhancing layer 12 is provided between the terminal pad 3 and the composite barrier metal layer 5, as shown in FIG. 2. The configuration of the present embodiment is otherwise identical to that of the previously described Embodiment 1.

The adhesion-enhancing layer 12 is formed from a material that adheres well both to the terminal pad 3 and to the composite barrier metal layer 5. Specifically, the material of the adhesion-enhancing layer 12 differs depending on the material of the terminal pad 3, but is preferably Ni, Cu, Fe, Co, Pd, Ti, Cr, W, or another such metal; or an alloy or other material primarily composed of these metals. To improve adhesion with the composite barrier metal layer 5, the material may also be the same as the material that forms the metal base phase 6 of the composite barrier metal layer 5; i.e., the material may be NiP. As described above, the adhesion-enhancing layer 12 is provided in order to improve adhesion between the terminal pad 3 and the composite barrier metal layer 5, and therefore need not be particularly thick. The thickness may, for example, be 0.1 μm or greater, and specifically 0.5 μm

In the present embodiment, providing the adhesion-enhancing layer 12 can improve adhesion between the terminal pad 3 and the composite barrier metal layer 5 in comparison with Embodiment 1. In normal applications, sufficient adhesion between the terminal pad 3 and the composite barrier metal layer 5 is ensured simply by forming the composite barrier metal layer 5 on the terminal pad 3. However, in the case of a device with a large chip and a large amount of thermal stress, or in cases in which the device could suffer impact from a drop, it is effective in terms of improving bond reliability to provide the adhesion enhancing layer 12 and to further improve adhesion between the terminal pad 3 and the composite barrier metal layer 5. The effects of the present embodiment are otherwise the same as those of the previously described Embodiment 1.

### Embodiment 4

Next, Embodiment 4 of the present invention will be described. The present embodiment is an embodiment of the method for manufacturing the semiconductor device according to the previously described Embodiment 3. In the present embodiment, the adhesion-enhancing layer 12 is formed by performing a zincate treatment, then dipping a silicon wafer in an electroless NiP plating bath that does not contain low-elasticity particles, and forming an NiP layer to a thickness of 0.1 μm, for example, and specifically 0.5 μm, as shown in FIG. 2. The thickness of the adhesion-enhancing layer 12 can be arbitrarily controlled according to the plating time, plating temperature, and other such conditions. The composite barrier metal layer 5 is then formed by the same method as in Embodiment 2 previously described. The configuration and effects of the present embodiment are otherwise the same as those of Embodiment 2 previously described.

### Embodiment 5

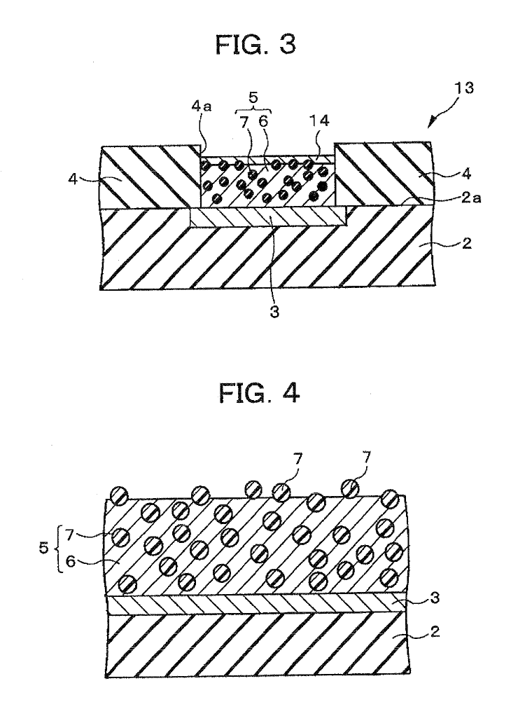

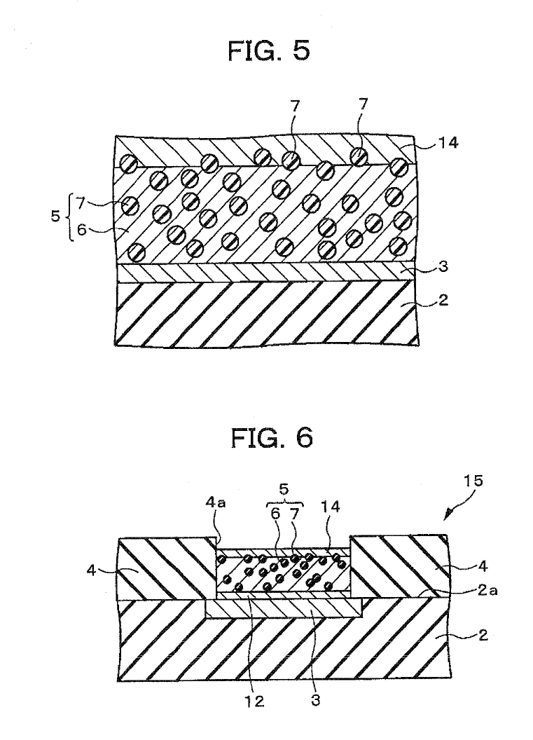

Next, Embodiment 5 of the present invention will be described. FIG. 3 is a cross-sectional view showing the semiconductor device according to the present embodiment, FIG. 4 is a partially enlarged cross-sectional view showing a semiconductor device that is not provided with a detachment prevention layer, and FIG. 5 is a partially enlarged cross-sectional view showing the semiconductor device according to the present embodiment. The semiconductor device 13 according to the present embodiment differs from the semiconductor device 1 (see FIG. 1) according to the previously described Embodiment 1 in that a detachment prevention layer 14 for preventing the low-elasticity particles 7 from being shed is provided on the surfaces of the composite barrier metal layer 5, as shown in FIG. 3. The configuration of the present embodiment is otherwise the same as that of Embodiment 1.

The detachment prevention layer 14 is composed of an electroconductive layer that does not contain low-elasticity particles 7, and is formed from a metal or an alloy containing one or more metals selected from, e.g., Ni, Cu, Fe, Co, Pd, Ti Cr, and W. Also, for example, the detachment prevention layer can be formed from the same material as the metal base phase 6 of the composite barrier metal layer 5, i.e., NiP. The detachment prevention layer 14 preferably has a thickness greater than the size of the low-elasticity particles 7. In cases in which the low-elasticity particles 7 are, e.g., 2 μm in size, the detachment prevention layer 14 is preferably 2 μm thick.

The following is a description of the effects of the present embodiment configured as described above. In cases in which the detachment prevention layer 14 (see FIG. 3) is not provided on the composite barrier metal layer 5, the metal base phase 6 is not completely embedded, and some low-elasticity particles 7 are exposed on the surface of the composite barrier metal layer 5, as shown in FIG. 4. These exposed low-elasticity particles 7 are sometimes shed during transportation of the silicon wafer, and contaminate the surface of the silicon wafer. To overcome this problem, the detachment prevention layers 14 can be provided on the composite barrier metal layer 5 to embed the low-elasticity particles 7 with the aid of the metal base phase 6 and the detachment prevention layer 14, and to prevent the low-elasticity particles 7 from being shed.

All of the low-elasticity particles 7 can be covered and shedding of the low-elasticity particles 7 can be completely prevented by forming the detachment prevention layer 14 with a thickness greater than the size of the low-elasticity particles 7. If half or more of the low-elasticity particles 7 are embedded instead of being completely covered, a consistent effect can still be achieved because the particles are not likely to detach. For example, the thickness of the detachment prevention layer 14 is 1 μm or greater in cases in which the low-elasticity particles 7 are 2 μm or more in diameter.

Productivity falls if the detachment prevention layer 14 is thicker than necessary; therefore, the thickness of the detachment prevention layer 14 in practice is preferably, e.g., about 1 to 5 μm.

Furthermore, the composite barrier metal layer 5 essentially has excellent solder-bonding properties, unlike a conventional electroconductive resin, anisotropic electroconductive film, or the like, but the solder-bonding properties can be further improved by providing the detachment prevention layer 14. The effects of the present embodiment are otherwise the same as those of the previously described Embodiment 1.

### Embodiment 6

Next, Embodiment 6 of the present invention will be described. The present embodiment is an embodiment of the method for manufacturing the semiconductor device according to the previously described Embodiment 5. In the present embodiment, after the composite barrier metal layer 5 is formed, a silicon wafer is dipped in an electroless NiP plating bath that does not contain low-elasticity particles, and an NiP layer is formed to a thickness of, e.g., 2 μm to form a detachment prevention layer 14 composed of NiP, as shown in FIG. 3. The thickness of the detachment prevention layer 14 can be arbitrarily controlled according to the plating time, plating temperature, and other such conditions. The configuration and effects of the present embodiment are otherwise the same as those of Embodiment 2 previously described.

### Embodiment 7

Next, Embodiment 7 of the present invention will be described. FIG. 6 is a cross-sectional view showing the semiconductor device according to the present embodiment. The present embodiment is a combination of Embodiments 3 and 5, as shown in FIG. 6. Specifically, in the semiconductor device 15 according to the present embodiment, an adhesion-enhancing layer 12 is provided between the terminal pad 3 and the composite barrier metal layer 5, and detachment prevention layer 14 is provided over the composite barrier metal layer 5. The configuration of the present embodiment is otherwise the same as that of the previously described Embodiment 1. The method for manufacturing the semiconductor device 15 according to the present embodiment combines the previously described Embodiment 4 and 6. Specifically, the adhesion-enhancing layer 12, the composite barrier metal layer 5, and the detachment prevention layer 14 are formed in sequence by sequentially dipping a silicon wafer in three electroless NiP plating baths.

According to the present embodiment, adhesion between the terminal pad 3 and the composite barrier metal layer 5 can be improved by providing the adhesion-enhancing layer 12. The low-elasticity particles 7 can also be prevented from being shed by providing the detachment prevention layer 14.

### Embodiment 8

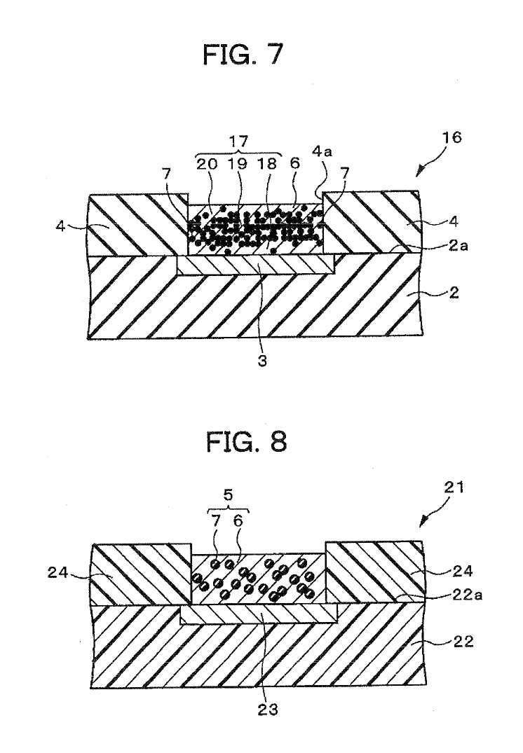

Next, Embodiment 8 of the present invention will be described. FIG. 7 is a cross-sectional view showing the semiconductor device according to the present embodiment. The configuration of the semiconductor device 16 according to the present embodiment resembles the configuration of the semiconductor device 15 according to the previously described Embodiment 7, but differs in the absence of a clearly defined interface between the adhesion-enhancing layer 12 and composite barrier metal layer 5, and a clearly defined interface between the composite barrier metal layer 5 and detachment prevention layer 14, as shown in FIG. 7. Specifically, in the present embodiment, a composite barrier metal layer 17 is provided instead of the stacked films comprising the adhesion-enhancing layer 12, the composite barrier metal layer 5, and the detachment prevention layer 14 in the previously described Embodiment 7. This composite barrier metal layer 17 includes, stacked in the following order from the terminal pad 3 side upward, a layer 18 poor in low-elasticity particles, a layer 19 rich in low-elasticity particles, and a layer 20 poor in low-elasticity particles. However, there are no clear borders between these layers. The content ratio of low-elasticity particles 7 is low in the layer 18 poor in low-elasticity particles, increases progressively from the layer 18 poor in low-elasticity particles to the layer 19 rich in low-elasticity particles, reaches a substantially constant maximum in the layer 19 rich in low-elasticity particles, decreases progressively from the layer 19 rich in low-elasticity particles to the layer 20 poor in low-elasticity particles, and is then low again in the layer 20 poor in low-elasticity particles. Specifically, the content ratio of the low-elasticity particles 7 in the composite barrier metal layer 17 continuously varies in the thickness direction of the composite barrier metal layer 17, and the content ratio of low-elasticity particles 7 in the bottom layer (layer 18 poor in low-elasticity particles) and top layer (layer 20 poor in low-elasticity particles) of the composite barrier metal layer 17 is less than the content ratio of low-elasticity particles 7 in the middle (layer 19 rich in low-elasticity particles) between the bottom and top layers. The configuration of the present embodiment is otherwise the same as that of the previously described Embodiment 1.

In the present embodiment, the content of low-elasticity particles 7 continuously varies throughout the composite barrier metal layer 17, and there is no clear interface in the composite barrier metal layer 17. Therefore, it is possible to prevent situations in which applied stress concentrates in the interface and the interface peels off, in contrast to cases in which interfaces are formed between the adhesion-enhancing layer 12, the composite barrier metal layer 5, and the detachment prevention layer 14, as in Embodiment 7 previously described. The bond reliability in the semiconductor device can thereby be further improved.

### Embodiment 9

Next, Embodiment 9 of the present invention will be described. The present embodiment is an embodiment of the method for manufacturing the semiconductor device according to the previously described Embodiment 8. The surface of the terminal pad 3 is subjected to a zincate treatment, and the silicon wafer is dipped in an electroless plating NiP solution that contains a silicone resin and that has a surfactant added thereto, as shown in FIG. 7. The silicon wafer is sequentially dipped in three electroless plating NiP baths to sequentially form the adhesion-enhancing layer 12, the composite barrier metal layer 5, and the detachment prevention layer 14 at this time in Embodiment 7. In the present embodiment, however, the silicon wafer is dipped in a single electroless NiP plating bath, and the film-forming conditions are varied during formation of the composite barrier metal layer 17, whereby a composite barrier metal layer 17 is formed in this single electroless NiP plating bath so that the layer 18 poor in low-elasticity particles, the layer 19 rich in low-elasticity particles, and the layer 20 poor in low-elasticity particles are stacked in sequence.

With electroless plating, the content ratio of low-elasticity particles 7 in the composite barrier metal layer 17 can be varied by adjusting the temperature, the pH, and the stirring conditions of the NiP plating solution, and other such factors. This is because the amount of low-elasticity particles 7 incorporated into the metal base phase 6 (NiP) depends on the rate of precipitation of the NiP, and the rate of precipitation of the NiP can be easily controlled by varying the temperature or pH of the solution.

In the stage of forming the layers 18 poor in low-elasticity particles as adhesion-enhancing layers as shown in FIG. 7, the solution temperature is set low at about 80 degrees, for example, and the amount of low-elasticity particles 7 incorporated in the film is reduced. Next, in the stage of forming the layer 19 rich in low-elasticity particles, the solution temperature is increased to, e.g., 90 degrees, and the rate of precipitation is improved to increase the amount of incorporated low-elasticity particles 7. Next, in the stage of forming the layer 20 poor in low-elasticity particles as detachment prevention layers, the temperature is again lowered to about 80 degrees to reduce the rate of precipitation. It is thereby possible to form a composite barrier metal layer 17 wherein the content ratio of low-elasticity particles 7 continuously varies. The previously described bath temperature is only one example, and in practice, the conditions must be set each time because the temperature dependence of the content ratio of low-elasticity particles varies according to the amount of low-elasticity particles in the plating bath and the type of surfactant.

In the present embodiment, an example was shown in which the content ratio of low-elasticity particles 7 in the composite barrier metal layer 17 was varied in three stages and films were formed corresponding to the three layers including the adhesion-enhancing layer 12, the composite barrier metal layer 5, and the detachment prevention layer 14 shown in the previously described Embodiment 7, but the present invention is not limited to this option alone. Another option is to vary the content ratio of low-elasticity particles 7 in the composite barrier metal layer 17 in two stages, and to form films corresponding to the two layers, which may be either the adhesion-enhancing layer and the composite barrier metal layer, or the composite barrier metal layer and the detachment prevention layer. The method for forming these films can be the same method for forming the three layers described above.

### Embodiment 10

Next, Embodiment 10 of the present invention will be described. FIG. 8 is a cross-sectional view showing the wiring board according to the present embodiment. In the present embodiment, a composite barrier metal layer is formed on the wiring board. In the wiring board 21 according to the present embodiment, a wiring board main body 22 composed of, e.g., a resin is provided, and a terminal pad 23 composed of, e.g., Al is formed on a surface 22a in the wiring board main body 22 on which a semiconductor device is mounted, as shown in FIG. 8. A solder resist 24 is provided on the mounting surface 22a of the wiring board main body 22, and an aperture 24a is formed in the area of the solder resist 24 that is directly above the terminal pads 23. A composite barrier metal layer 5 is provided over the terminal pad 3; i.e., in the aperture 24a. The configuration of the composite barrier metal layer 5 is the same as that of the composite barrier metal layer 5 in the previously described Embodiment 1.

The following is a description of the operation of the wiring board according to the present embodiment configured as described above. In the wiring board 21 according to the present embodiment, a solder bump (not shown) is mounted on the composite barrier metal layer 5, and a semiconductor device is mounted with the aid of the solder bump to form a semiconductor package. Specifically, the semiconductor device is disposed on the side of the wiring board main body 22 facing the mounting surface 22a. The terminal pad 23 of the wiring board main body 22 is bonded to the terminal pad of the semiconductor device by means of the composite barrier metal layer 5 and the solder bump.

When the semiconductor package undergoes a heat cycle, thermal stress is created between the wiring board 21 and the semiconductor device as a result of the difference in thermal expansion coefficients between the wiring board 21 and the semiconductor device. At this time, the low-elasticity particles 7 in the composite barrier metal layer 5 undergoes deformation, whereby the entire composite barrier metal layer 5 is deformed and the thermal stress is absorbed.

Next, the effects of the present embodiment will be described. In the wiring board 21 according to the present embodiment, when thermal stress is created between the wiring board 21 and the semiconductor device mounted on the wiring board 21, the deformation and absorption of thermal stress by the composite barrier metal layer 5 can prevent the solder bump from being damaged. As a result of providing the composite barrier metal layer 5, the solder can be prevented from diffusing into the terminal pad 3 and the wiring board main body 22 during melting of the solder bump. Since the metal base phase 6 of the composite barrier metal layer 5 is formed from NiP, which has low electrical resistivity, providing the composite barrier metal layers 5 can prevent electrical resistance between the terminal pad 23 and the solder bump from increasing.

### Embodiment 11

Next, Embodiment 11 of the present invention will be described. The present embodiment is an embodiment of the method for manufacturing the wiring board according to the previously described Embodiment 10. As shown in FIG. 8, first, a wiring board main body 22 composed of, e.g., a resin is provided, the necessary wiring and the like are formed, and a terminal pad 23 composed of Al is formed on the mounting surface 22a of the semiconductor device. Next, a solder resist 24 is formed on the mounting surface 22a of the wiring board main body 22. An aperture 24a is formed in the solder resist 24 in the area directly above the terminal pad 23 to expose the terminal pad 23.

Next, the surface of the terminal pad 23 is subjected to a zincate treatment, and electroless NiP plating is then applied to form a composite barrier metal layer 5. The method for forming the composite barrier metal layer 5 is the same as in Embodiment 2 previously described. The wiring board main body 22 is thereby manufactured.

In the present embodiment, the composite barrier metal layer 5 can be formed by means of the method described above, without using more steps than when a conventional barrier metal layer without low-elasticity particles is formed. The composite barrier metal layer 5 can thereby be formed at low cost and high productivity.

### Embodiment 12

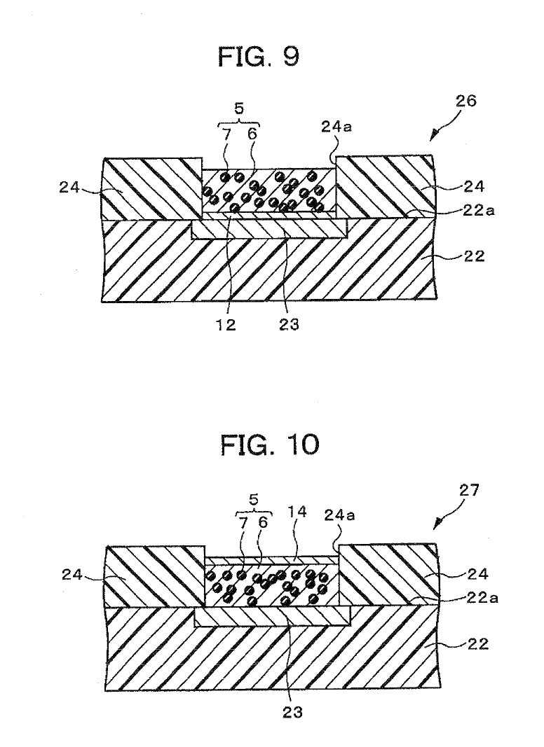

Next, Embodiment 12 of the present invention will be described. FIG. 9 is a cross-sectional view showing the wiring board according to the present embodiment. The wiring board 26 according to the present embodiment differs from the wiring board 21 (see FIG. 8) according to the previously described Embodiment 10 in that an adhesion enhancing layer 12 is provided between a terminal pad 23 and a composite barrier metal layer 5, as shown in PIG. 9. The configuration of the adhesion-enhancing layer 12 is the same as that of the adhesion-enhancing layer 12 (see FIG. 2) in the previously described Embodiment 3. The configuration in the present embodiment is otherwise identical to that of the previously described Embodiment 10. The method for manufacturing the wiring board 26 according to the present embodiment is the same as the method for manufacturing the wiring board shown in the previously described Embodiment 11, with the addition of the method for forming the adhesion-enhancing layer 12 shown in the previously described Embodiment 4. The effects of the present embodiment are the same as the effects of the previously described Embodiment 10, with the addition of the effects of the previously described Embodiment 3.

### Embodiment 13

Next, Embodiment 13 of the present invention will be described. FIG. 10 is a cross-sectional view showing the wiring board according to the present embodiment. The wiring board 27 according to the present embodiment differs from the wiring board 21 (see FIG. 8) according to the previously described Embodiment 10 in that a detachment prevention layer 14 is provided over the composite barrier metal layer 5. The configuration of the detachment prevention layer 14 is the same as that of the detachment prevention layer 14 (see FIG. 3) in the previously described Embodiment 5. The configuration of the present embodiment is otherwise identical to the previously described Embodiment 10. The method for manufacturing the wiring board 27 according to the present embodiment is the same as the method for manufacturing the wiring board shown in the previously described Embodiment 11, with the addition of the method for forming the detachment prevention layer 14 shown in the previously described Embodiment 6. The effects of the present embodiment are the same as the effects of the previously described Embodiment 10, with the addition of the effects of the previously described Embodiment 5.

### Embodiment 14

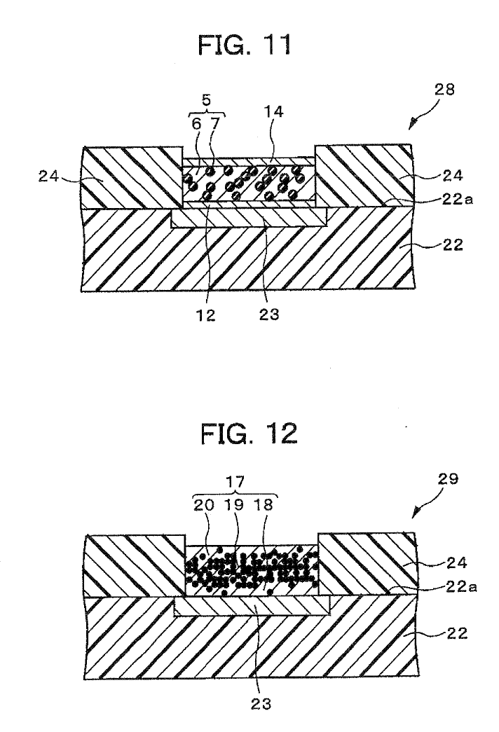

Next, Embodiment 14 of the present invention will be described. FIG. 11 is a cross-sectional view showing the wiring board according to the present embodiment. As shown in FIG. 11, the wiring board 28 according to the present embodiment differs from the wiring board 21 (see FIG. 8) according to the previously described Embodiment 10, in that an adhesion-enhancing layer 12 is provided between the terminal pad 23 and the composite barrier metal layer 5, and a detachment prevention layer 14 is provided over the composite barrier metal layer 5. The configuration of the adhesion-enhancing layer 12 is the same as that of the adhesion-enhancing layer 12 (see FIG. 2) in the previously described Embodiment 3, and the configuration of the detachment prevention layer 14 is the same as that of the detachment prevention layer 14 (see FIG. 3) in the previously described Embodiment 5. The configuration of the present embodiment is otherwise identical to that of the previously described Embodiment 10. The method for manufacturing the wiring board 28 according to the present embodiment is the same as the method for manufacturing the wiring board shown in the previously described Embodiment 11, with the addition of the method for forming the adhesion-enhancing layer 12 shown in the previously described Embodiment 4, and the method for forming the detachment prevention layer 14 shown in the previously described Embodiment 6. The effects of the present embodiment are the same as the effects of the previously described Embodiment 10, with the addition of the effects of the previously described Embodiments 3 and 5.

### Embodiment 15

Next, Embodiment 15 of the present invention will be described. FIG. 12 is a cross-sectional view showing the wiring board according to the present embodiment. As shown in FIG. 12, the wiring board 29 according to the present embodiment differs from the wiring board 28 (see FIG. 11) according to the previously described Embodiment 14 in that a composite barrier metal layer 17 is provided instead of a stacked film composed of an adhesion-enhancing layer 12, a composite barrier metal layer 5, and a detachment prevention layer 14. The configuration of the composite barrier metal layer 17 is the same as that of the composite barrier metal layer 17 (see FIG. 7) in the previously described Embodiment 8. The configuration of the present embodiment is otherwise identical to that of the previously described Embodiment 10. The method for manufacturing the wiring board 29 according to the present embodiment is the same as the method for manufacturing the wiring board shown in the previously described Embodiment 11, except that instead of forming a stacked film composed of an adhesion-enhancing layer 12, a composite barrier metal layer 5, and a detachment prevention layer 14, the composite barrier metal layer 17 is formed by means of the method shown in the previously described Embodiment 9. The effects of the present embodiment are the same as the effects of the previously described Embodiment 10, with the addition of the effects of the previously described Embodiment 8.

### Embodiment 16

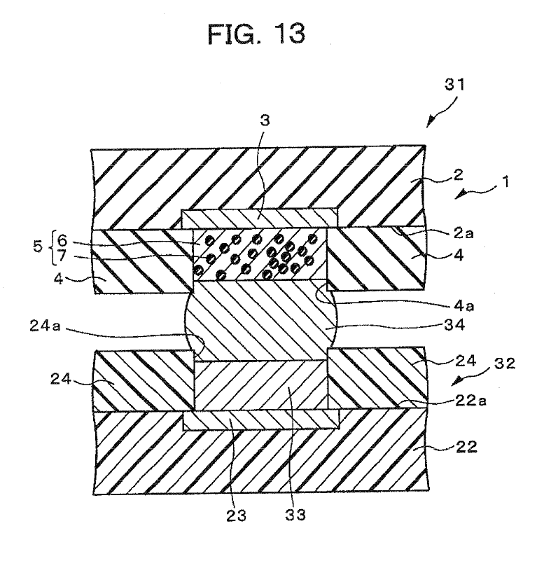

Next, Embodiment 16 of the present invention will be described. FIG. 13 is a cross-sectional view showing the semiconductor package according to the present embodiment. The semiconductor package 31 is provided with the semiconductor device 1 according to the previously described Embodiment 1, and the semiconductor device 1 is mounted on a wiring board 32, as shown in FIG. 13. The configuration of the semiconductor device 1 is as described in Embodiment 1.

The wiring board 32 is a conventional wiring board. Specifically, the wiring board 32 is provided with a wiring board main body 22 composed of, e.g., a resin; and a terminal pad 23 composed of, e.g., Al is formed on a surface thereof. A solder resist 24 is provided on the mounting surface 22a of the wiring board main body 22, and an aperture 24a is formed in the solder resist 24 in the area directly over the terminal pad 23. Also, a barrier metal layer 33 composed of, e.g., NiP is provided in the aperture 24a; i.e., over the terminal pad 23.

A solder bump 34 is provided over the barrier metal layer 33 on the wiring board 32, and the barrier metal layer 33 is bonded to the composite barrier metal layer 5 of the semiconductor device 1 via the solder bump 34. The solder bump 34 is formed from, e.g., the eutectic SnPb, but the bump may also be formed from high-temperature SnP, or from a lead-free solder such as an SnAg-based solder, an SnZn-based solder, an SnAgCu-based solder, an SnCu-based solder, or the like.

The method for manufacturing the semiconductor device 1 is the same as the manufacturing method according to Embodiment 2. The barrier metal layer 33 of the wiring board 32 and the composite barrier metal layer 5 of the semiconductor device 1 can be connected with the aid of the solder bump 34 by using a conventional solder bonding process. The action and effects of the present embodiment are the same as those of the previously described Embodiment 1.

### Embodiment 17

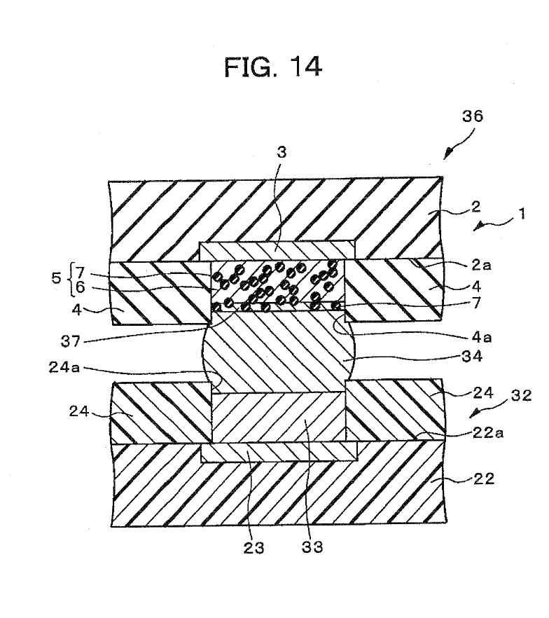

Next, Embodiment 17 of the present invention will be described. FIG. 14 is a cross-sectional view showing the semiconductor package according to the present embodiment. The semiconductor package 36 according to the present embodiment differs from the semiconductor package 31 according to the previously described Embodiment 16 in that an intermetallic compound layer 37 is formed on the surface of the composite barrier metal layer 5, and this intermetallic compound layer 37 also contains low-elasticity particles 7, as shown in FIG. 14. The intermetallic compound layer 37 is formed by alloying the NiP that forms the metal base phase 6 of the composite barrier metal layer 5, and the solder that forms the solder bump 34.

When the solder bump 34 on the composite barrier metal layers 5 is melted, an alloying reaction takes place between the metal base phase 6 of the composite barrier metal layer 5 and the solder of the solder bump 34, and the intermetallic compound layer 37 is formed, whereupon cracks tend to form in the intermetallic compound layer 37 and cause wire breakage to occur when the package is subjected to impact from a drop or the like. However, when low-elasticity particles 7 are dispersed throughout the intermetallic compound layer 37, the cracks can be prevented from suddenly spreading through the intermetallic compound layer 37 during impact, wire breakage can be prevented, and the semiconductor package can be made more reliable. The result is the most pronounced in cases in which the low-elasticity particles 7 are formed from a silicone resin having excellent impact absorption capacity, but this result can still be obtained in cases in which the low-elasticity particles 7 are formed from a fluorine resin, an acrylic resin, a nitrile resin, a urethane resin, or another such resin.

The method for manufacturing the semiconductor package 36 according to the present embodiment is the one described in the previously described Embodiment 16. In this method, in order for the intermetallic compound layer 37 to contain a greater amount of low-elasticity particles 7, the low-elasticity particles 7 can be made larger to increase the volume ratio of the low-elasticity particles 7 incorporated into the intermetallic compound layer 37 even with the same number of low-elasticity particles 7 incorporated into the intermetallic compound layer 37. Alternatively, the content ratio of low-elasticity particles 7 in the electroless NiP plating bath can be raised to increase the number of low-elasticity particles 7 incorporated into the intermetallic compound layer 37. This result can also be achieved by omitting the detachment prevention layer 14 and reducing the thickness.

### Embodiment 18

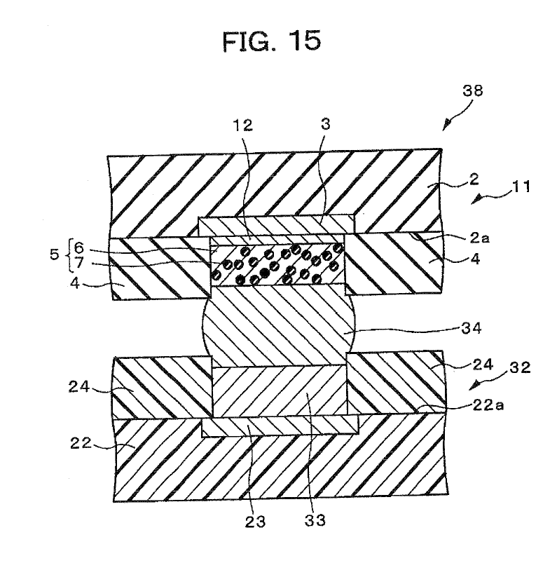

Next, Embodiment 18 of the present invention will be described. FIG. 15 is a cross-sectional view showing the semiconductor package according to the present embodiment. The semiconductor package 38 according to the present embodiment differs from the semiconductor package 31 according to the previously described Embodiment 16 by the use of the semiconductor device 11 (see FIG. 2) according to the previously described Embodiment 3; i.e., a semiconductor device in which an adhesion-enhancing layer 12 is provided between the terminal pad 3 and the composite barrier metal layer 5, as shown in FIG. 15. The configuration of the present embodiment is otherwise the same as that of the previously described Embodiment 16. The semiconductor package 38 according to the present embodiment can be manufactured by the manufacturing method of the previously described Embodiment 16, with the addition of the step for forming the adhesion-enhancing layer 12 in the previously described Embodiment 4. The effects of the present embodiment are the same as those of the previously described Embodiment 3.

### Embodiment 19

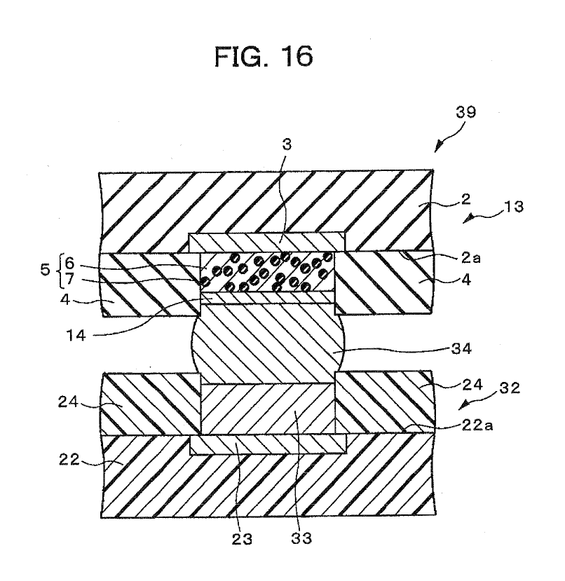

Next, Embodiment 19 of the present invention will be described. FIG. 16 is a cross-sectional view showing a semiconductor package according to the present embodiment.

The semiconductor package 39 according to the present embodiment differs from the semiconductor package 31 according to the previously described Embodiment 16 by the use of the semiconductor device 13 (see FIG. 3) according to the previously described Embodiment 5; i.e., a semiconductor device wherein a detachment prevention layer 14 is provided over the composite barrier metal layer 5, as shown in FIG. 16. The configuration of the present embodiment is otherwise the same as that of the previously described Embodiment 16. The semiconductor package 39 according to the present embodiment can be manufactured by the manufacturing method of the previously described Embodiment 16, with the addition of the step for forming the detachment prevention layer 14 in the previously described Embodiment 6. The effects of the present embodiment are the same as those of the previously described Embodiment 5.

### Embodiment 20

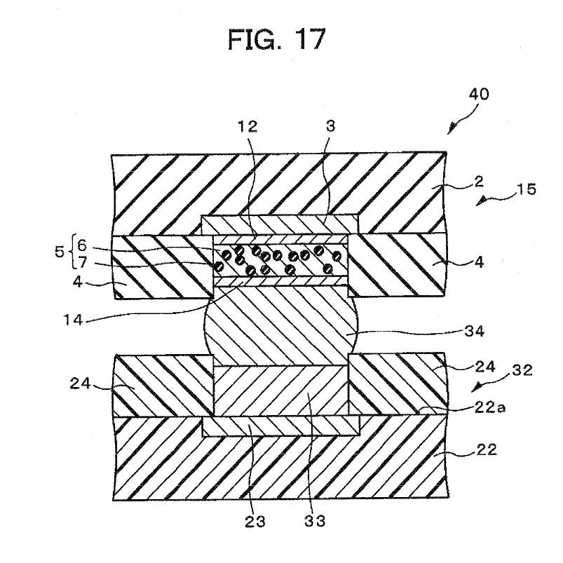

Next, Embodiment 20 of the present invention will be described. FIG. 17 is a cross-sectional view showing the semiconductor package according to the present embodiment. The semiconductor package 40 according to the present embodiment differs from the semiconductor package 31 according to the previously described Embodiment 16 by the use of the semiconductor device 15 (see FIG. 6) according to the previously described Embodiment 7; i.e., a semiconductor device in which an adhesion-enhancing layer 12 is provided between the terminal pad 3 and the composite barrier metal layer 5, and a detachment prevention layer 14 is provided over the composite barrier metal layer 5, as shown in FIG. 17. The configuration of the present embodiment is otherwise the same as that of the previously described Embodiment 16. The semiconductor package 40 according to the present embodiment can be manufactured by the manufacturing method of the previously described Embodiment 16, with the addition of the step for forming the adhesion-enhancing layer 12 in the previously described Embodiment 4, and the step for forming the detachment prevention layer 14 in the previously described Embodiment 6. The effects of the present embodiment are the same as those of Embodiment 7 previously described.

### Twenty-Embodiment 1

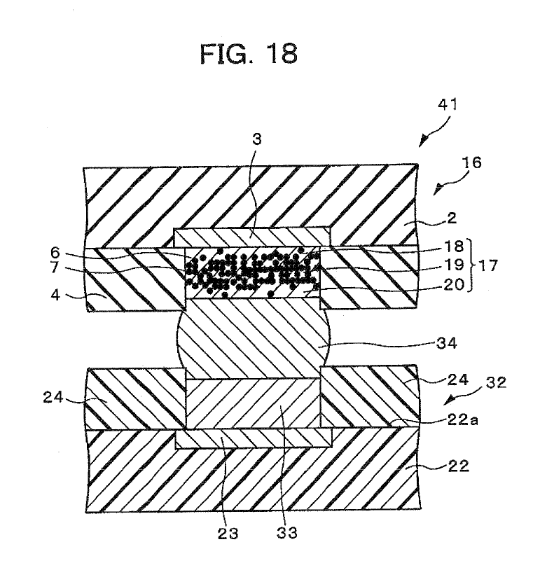

Next, the twenty-Embodiment 1 of the present invention will be described. FIG. 18 is a cross-sectional view showing the semiconductor package according to the present embodiment. The semiconductor package 41 according to the present embodiment differs from the semiconductor package 31 according to the previously described Embodiment 16 by the use of the semiconductor device 16 (see FIG. 7) according to the previously described Embodiment 8; i.e., a semiconductor device in which an adhesion-enhancing layer 12, a composite barrier metal layer 5, or a detachment prevention layer 14 is replaced with a composite barrier metal layer 17 wherein the content ratio of low-elasticity particles 7 continuously varies in the film thickness direction, as shown in FIG. 18. The configuration of the present embodiment is otherwise the same as that of the previously described Embodiment 16. The semiconductor package 41 according to the present embodiment can be manufactured by the manufacturing method of the previously described Embodiment 16, wherein the step for forming the composite barrier metal layer 17 in the previously described Embodiment 9 is performed instead of the steps for forming the adhesion-enhancing layer 12, the composite barrier metal layer 5, and the detachment prevention layer 14. The effects of the present embodiment are the same as those of Embodiment 8 previously described.

### Embodiment 22

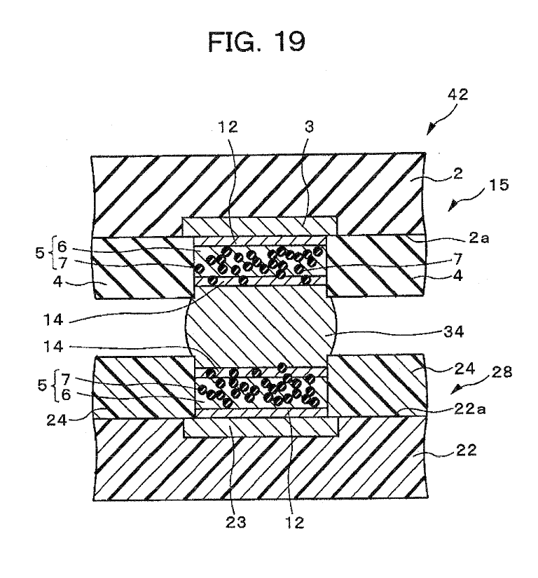

Next, Embodiment 22 of the present invention will be described. FIG. 19 is a cross-sectional view showing the semiconductor package according to the present embodiment. The semiconductor package 42 according to the present embodiment differs from the semiconductor package 31 according to the previously described Embodiment 16 by the use of the semiconductor device 15 (see FIG. 6) according to the previously described Embodiment 7; i.e., a semiconductor device wherein an adhesion-enhancing layer 12 is provided between the terminal pad 3 and the composite barrier metal layer 5, and a detachment prevention layer 14 is provided over the composite barrier metal layer 5. The semiconductor package 42 also differs by the use of the wiring board 28 (see FIG. 11) according to the previously described Embodiment 14; i.e., a wiring board wherein an adhesion-enhancing layer 12 is provided between the terminal pad 23 and the composite barrier metal layer 5, and a detachment prevention layer 14 is provided over the composite barrier metal layer 5. The configuration of the present embodiment is otherwise the same as that of the previously described Embodiment 16.

In the semiconductor package of the present invention, the effects of reducing stress are obtained by providing a composite barrier metal layer 5 over the terminal pad of the semiconductor device and/or the wiring board bonded via the solder bump 34, but providing the composite barrier metal layer 5 over the terminal pads of both the semiconductor device and the wiring board as in the present embodiment yields greater effects of reducing stress and absorbing impact.

The semiconductor package according to the present invention is not limited to those shown in the previously described Embodiments 16 through 21, and can also be an arbitrary combination of the semiconductor devices according to the previously described Embodiments 1, 5, 7, and 8; and the wiring boards according to the previously described Embodiments 10 and 12 through 15. A conventional semiconductor device may also be mounted on any of the wiring boards according to the previously described Embodiments 10 and 12 through 15. Furthermore, combinations may be used in which semiconductor devices or wiring boards are bonded with each other.

### Embodiment 23

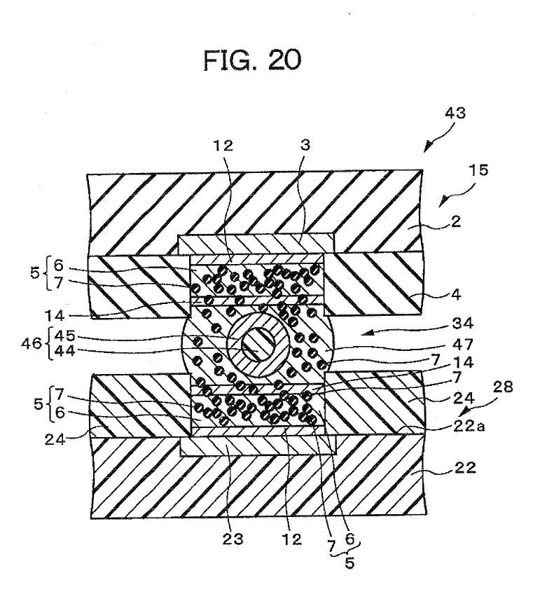

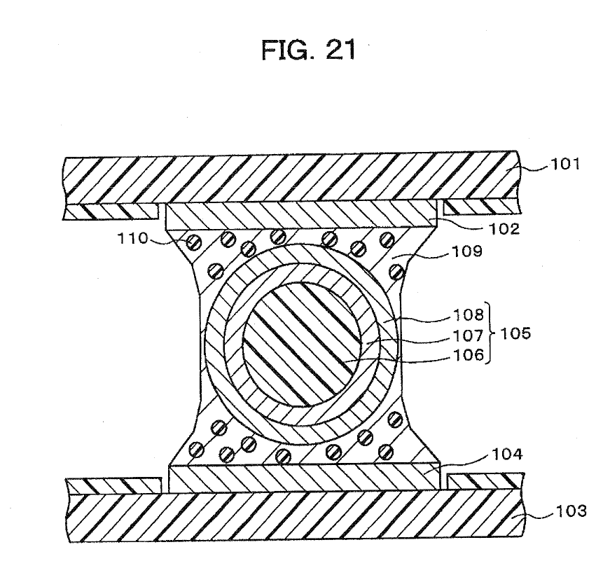

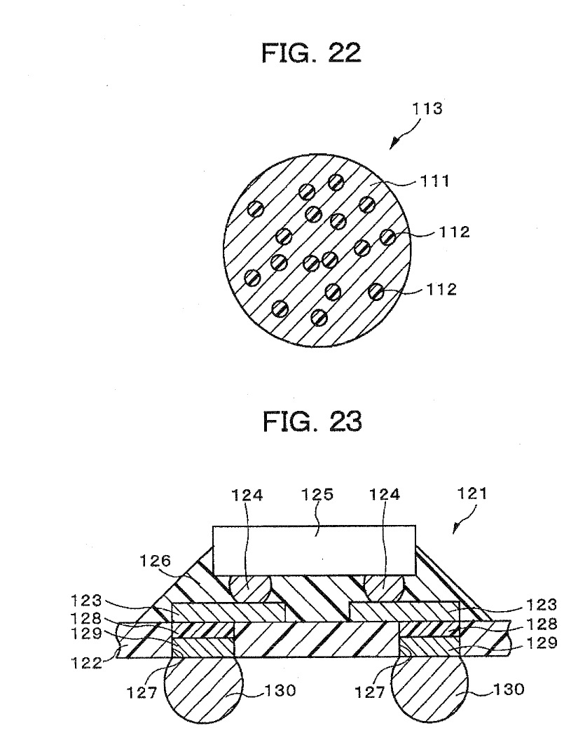

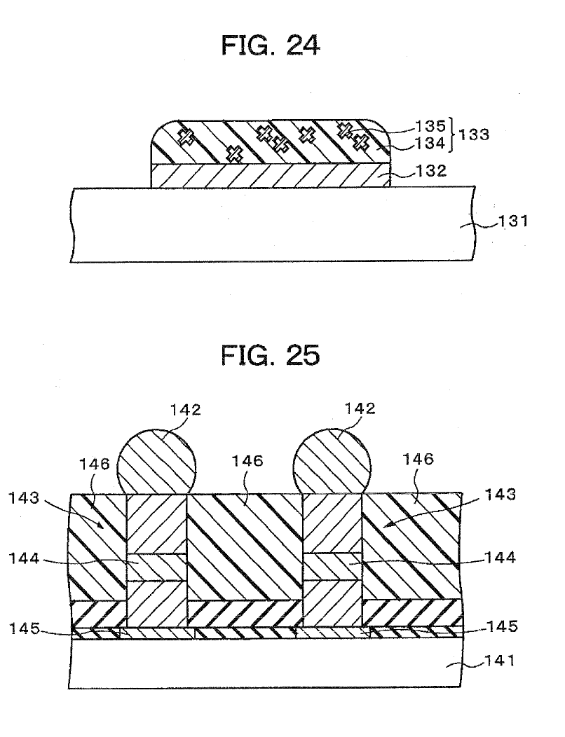

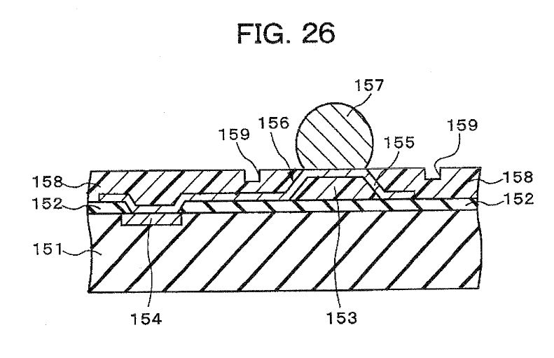

Next, Embodiment 23 of the present invention will be described. FIG. 20 is a cross-sectional view showing the semiconductor package according to the present embodiment. The semiconductor package 43 according to the present embodiment differs from the semiconductor package 42 according to the previously described Embodiment 22 in that the solder bump 34 is provided with a solder ball 46 in which a solder layer 45 covers the surface of a resinous core ball 44, and low-elasticity particles 7 are dispersed throughout solder paste 47 that forms the solder bump 34, as shown in FIG. 20. The configuration of the present embodiment is otherwise the same as that of the previously described Embodiment 22.

In the present embodiment, providing the solder bump 34 with a resinous core ball 44 and low-elasticity particles 7 causes a reduction in the strength of the solder bump 34 as such, but deformation is induced in the low-elasticity particles 7 inside the composite barrier metal layer 5, as well as in the core ball 44 and low-elasticity particles 7 inside the solder bump 34, whereby the displacement that accompanies thermal stress or an impact from a drop or the like can be more effectively absorbed. Therefore, the bond reliability of the semiconductor package can be improved even further by applying the present embodiment to a case in which the solder bump 34 is comparatively large and in which the strength of the solder bump 34 as such can be ensured to a certain extent.

### Embodiment 24

Next, Embodiment 23 of the present invention will be described. The electronic apparatus according to the present embodiment comprises any of the semiconductor devices according to the previously described Embodiment 1, 3, 5, 7 or 8; any of the wiring boards according to the previously described Embodiment 10 or 12 through 15; and any of the semiconductor packages according to the previously described Embodiments 16 through 23. The electronic apparatus according to the present embodiment may, for example, be a portable phone, a notebook computer, a desktop personal computer, a liquid crystal device, an interposer, or a module. According to the present embodiment, it is possible to obtain a highly reliable electronic apparatus that has an excellent capacity to reduce thermal stress and to absorb impact when dropped.

### INDUSTRIAL APPLICABILITY

The present invention can be suitably applied to a portable phone, a notebook computer, a desktop personal computer, a liquid crystal device, an interposer, a module, or another such electronic apparatus. Particularly, the present invention can be suitably applied to a portable electronic apparatus that has a high probability of dropping.

1-6. (canceled)

7. The semiconductor device according to claim 32, wherein the electroconductive material that forms the base phase of the barrier metal layer is a metal or an alloy containing one or more metals selected from the group consisting of Ni, Cu, Fe, Co, and Pd.

8. The semiconductor device according to claim 7, wherein the electroconductive material that forms the base phase of the barrier metal layer is NiₓP_{y} where x and y may be the same or different.

9. The semiconductor device according to claim 32, wherein the low-elasticity particles are formed from one, two, or more resins selected from the group consisting of a silicone resin, a fluorine resin, an acrylic resin, a nitrite resin, and a urethane resin.

10-31. (canceled)

32. A semiconductor device comprising:
a semiconductor chip having a terminal pad on a surface;
a passivation film provided over said surface, said passivation film having an aperture in an area directly above the terminal pad; and
a barrier metal layer provided on the terminal pad, the barrier metal layer connected to a solder bump,
wherein the barrier metal layer is a composite having a base phase composed of an electroconductive material and a plurality of low-elasticity particles that are dispersed in the base phase and that have lower modulus of elasticity than does the base phase, wherein the composite barrier metal layer absorbs thermal stress to prevent damage to the solder bump, and wherein the composite barrier metal layer is provided only in the aperture within the passivation film.
